(19) United States
(12) Patent Application Publication
(10) Pub. No.: US 2016/0226223 A1
(43) Pub. Date: Aug. 4, 2016

(54) VCSEL Packaging and VCSEL Array Configurations

(71) Applicant: Avago Technologies General IP (Singapore) Pte. Ltd, Singapore (SG)

(72) Inventors: Leonard Ian Kheng Tan, Singapore (SG); Chee Siong Peh, Singapore (SG); David Graham McIntyre, Bellingham, WA (US)

(21) Appl. No.: 14/610,161

(22) Filed: Jan. 30, 2015

(51) Int. Cl. H01S 5/42; H01S 5/042; F21V 8/00; H01S 5/022; H01S 5/40; H01S 5/183; H01S 5/02

(52) U.S. Cl. CPC H01S 5/423; H01S 5/183; H01S 5/0425; H01S 5/0206; H01S 5/02256; H01S 5/4025; G02B 6/0006

(57) ABSTRACT

Various VCSEL device packages and VCSEL array configurations are disclosed. In one example, a device contains two or more VCSELs, each VCSEL having a substantially triangular body. Such device packages allow for denser VCSEL array configurations than those provided by traditional VCSEL device packages. The denser VCSEL array configurations not only allow for more VCSELs to be batch manufactured per wafer but also allow for denser layouts on various mounting surfaces.

### FIELD OF THE INVENTION

The invention relates to optoelectronic devices, and more particularly, to vertical cavity surface emitting lasers (VCSELs).

### BACKGROUND

As is known, a vertical cavity surface emitting laser (VCSEL) is a type of semiconductor laser diode in which a laser beam is emitted perpendicular from a top surface of the device. Typically, a VCSEL is manufactured by singulating an individual VCSEL device from a batch of VCSEL devices that are simultaneously fabricated on a single wafer. FIG. 1 shows a prior art VCSEL 10 that has been manufactured in this manner. As can be seen, the prior art VCSEL 10 has a four-sided profile. The four-sided profile provides certain advantages when singulating a wafer because the singulating can be carried out by using a pattern of horizontal and vertical cutting axes.

FIG. 2 shows a VCSEL array 20 that includes a number of VCSELs arranged in a prior art configuration. In this example configuration, VCSEL array 20 contains three of the VCSELs 10 arranged side by side. In this traditional arrangement, the overall width “d3” of the VCSEL array 20 is determined by the width “d1” of each individual VCSEL 10 and by the inter-device spacing “d2” between any adjacent pair of VCSELs 10.

The overall width “d3” of the VCSEL array 20 can be minimized by reducing one or both of “d1” and “d2.” However, the extent to which “d1” can be reduced is constrained by the traditional four-sided packaging of the VCSEL 10. The extent to which “d2” can be reduced is constrained by minimum spacing requirements driven be various factors, such as for example, layout limitations, manufacturing limitations, and temperature-related limitations. Thus, the constraints imposed by “d1” and “d2” limit the number of VCSELs that can be included in a given area. This given area can correspond to a real estate area on a wafer thereby limiting the number of VCSELs that can be fabricated in each batch from the wafer. The given area can also correspond to a real estate area on a substrate (such as a printed circuit board, for example) thereby limiting the number of VCSELs that can be mounted on the substrate.

It is therefore desirable to provide VCSEL device packaging and array configurations that allow for denser arrangements on various surfaces. It will be further desirable to ensure that such device packaging and array configurations do not compromise performance and layout parameters.

### SUMMARY

Various types of VCSEL arrays and VCSEL array assemblies are disclosed herein. In accordance with a first example embodiment, a device includes a first VCSEL having a triangle shaped cross-section that extends from a top surface to a bottom surface of the first VCSEL. The first VCSEL has a first metal contact and a metallic annular ring located on the top surface. The metallic annular ring encircles an optical window comprising at least one of a transparent material or a translucent material through which light is propagated out of the first VCSEL.

In accordance with a second example embodiment, a device includes a set of VCSELs. Each VCSEL has an emitting surface on which is located an optical window and a metal contact. The device further includes a substrate on which the set of VCSELs is arranged in either an oval configuration or a circular configuration. The oval configuration or the circular configuration can be defined at least in part by the optical window of each of the set of VCSELs being located closer to a center of the oval configuration or the circular configuration than the metal contact on each of the set of VCSELs.

In accordance with a third example embodiment, a device includes a first, a second, and a third VCSEL. The first VCSEL has a top surface on which is located a first metal contact and a first optical window, the first optical window configured for propagating light out of the first VCSEL. The second VCSEL has a top surface on which is located a second metal contact and a second optical window, the second optical window configured for propagating light out of the second VCSEL. The third VCSEL has a top surface on which is located a third metal contact and a third optical window, the third optical window configured for propagating light out of the third VCSEL. The first optical window and the third optical window are aligned along a first horizontal axis and the second optical window is aligned along a second horizontal axis that is offset with respect to the first horizontal axis.

### BRIEF DESCRIPTION OF THE FIGURES

Many aspects of the invention can be better understood by referring to the following description in conjunction with the accompanying claims and figures. In the figures, like numerals indicate like structural elements and features. For clarity, not every element may be labeled with numerals in each figure. However, such unlabeled elements can be identified by referring to other figures where labeling is provided. The drawings are not necessarily drawn to scale, emphasis instead being placed upon illustrating the principles of the invention. The drawings should not be interpreted as limiting the scope of the invention to the example embodiments shown herein.

FIG. 1 shows a prior art VCSEL.

FIG. 2 shows a prior art VCSEL array that includes a number of the prior art VCSELs shown in FIG. 1.

FIG. 3 shows a top view of a VCSEL that constitutes an example light emitting element in accordance with the disclosure.

FIG. 4 shows a bottom view of the VCSEL shown in FIG. 3.

FIG. 5 shows a perspective view of the VCSEL shown in FIGS. 3 and 4.

FIG. 6 shows a first example embodiment of a VCSEL array in accordance with the disclosure.

FIG. 7 shows a top view of a second example embodiment of a VCSEL in accordance with the disclosure.

FIG. 8 shows a bottom view of the VCSEL shown in FIG. 7.

FIG. 9 shows a second example embodiment of a VCSEL array in accordance with the disclosure.

FIG. 10 shows a third example embodiment of a VCSEL array in accordance with the disclosure.

FIG. 11 shows a fourth example embodiment of a VCSEL array in accordance with the disclosure.

FIG. 12 shows a fifth example embodiment of a VCSEL array in accordance with the disclosure.

FIG. 13 shows a sixth example embodiment of a VCSEL array in accordance with the disclosure.

FIG. 14 shows a first example embodiment of a VCSEL array assembly that incorporates a VCSEL array in accordance with the disclosure.

FIG. 15 shows a planar light circuit (PLC) that can be coupled to the VCSEL array assembly shown in FIG. 14, in accordance with the disclosure.

FIG. 16 shows an optical assembly wherein the PLC shown in FIG. 15 is coupled with the VCSEL array assembly shown in FIG. 14, in accordance with the disclosure.

### WRITTEN DESCRIPTION

Generally, in accordance with illustrative embodiments described herein, devices, array arrangements, packages, and configurations are provided that pertain to one or more VCSELs. More particularly, a variety of device packages are disclosed with respect to individual VCSELs. These device packages allow for denser VCSEL array configurations than provided by traditional schemes. The denser VCSEL array configurations not only allow for more devices to be batch manufactured per wafer but also allow for denser packaging layouts on various mounting surfaces. Such mounting surfaces can include, for example, a printed circuit board (PCB) and/or a substrate of a hybrid-device package containing numerous components.

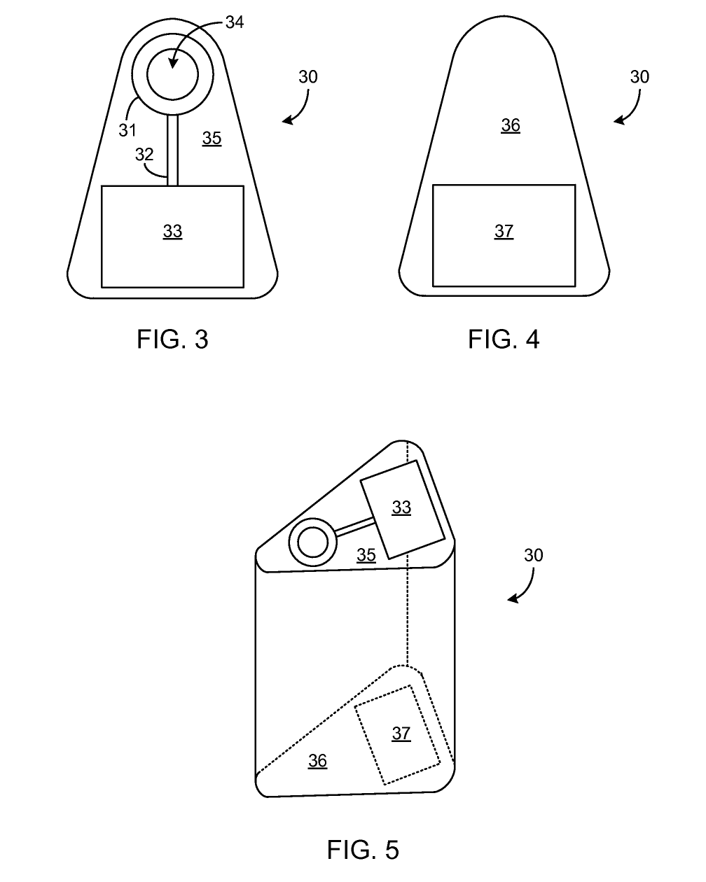

Attention is now drawn to FIG. 3, which shows a top view of a VCSEL 30 that constitutes one example light emitting element in accordance with the disclosure. In other embodiments, the light emitting element can be various other light emitting devices that emit light from a top surface. The top view indicates a top surface 35 on which is located a first metal contact 33, an annular ring 31, and a metallic strip 32. The metallic strip 32 interconnects the first metal contact 33 and the annular ring 31. The annular ring 31 encircles an optical window 34 that is made of a transparent material that permits light to exit the VCSEL 30 out through the optical window 34. In some implementations, optical window 34 is made of a translucent material (semi-transparent material) that selectively allows light of a certain wavelength to exit the VCSEL 30 out through the optical window 34. The first metal contact 33 can be implemented in a variety of ways, such as for example, in the form of a metal pad, a metal ball, or a metal layer.

FIG. 4 shows a bottom view of the VCSEL 30 shown in FIG. 3. The bottom view indicates a bottom surface 36 on which is located a second metal contact 37. The second metal 37 can be implemented in a variety of ways, such as for example, in the form of a metal pad, a metal ball, or a metal layer. A laser beam (not shown) is emitted out of the optical window 34 perpendicular to the top surface 35 of the VCSEL 30, when an electrical voltage is applied between the first metal contact 33 and the second metal contact 37. In a first example implementation, the first metal contact 33 is configured as an anode terminal of the VCSEL 30 and the second metal contact 37 is configured as a corresponding cathode terminal of the VCSEL 30. In a second example implementation, the first metal contact 33 is configured as a cathode terminal of the VCSEL 30 and the second metal contact 37 is configured as a corresponding anode terminal of the VCSEL 30.

One or both of the first metal contact 33 and the second metal contact 37 can have a square outline, a rectangular outline, a circular outline, an oval shaped outline, or an outline having a customized shape. The customized shape can be selected for example, in accordance with the shape of each of a top surface and a bottom surface of a VCSEL in accordance with the disclosure. Thus, the customized shape of one or both of the first metal contact 33 and the second metal contact 37 of the VCSEL 30 can be a smaller version of the triangular periphery of a respective one of the top surface 35 and the bottom surface 36.

FIG. 5 shows a perspective view of the VCSEL 30 shown in FIGS. 3 and 4. In this example embodiment, the VCSEL 30 has a substantially triangular body that is characterized by a substantially triangular cross-section at every point of the body of the VCSEL 30 extending from the top surface 35 to the bottom surface 36. It should be understood that the phrase “substantially triangular” as used herein not only encompasses a perfect triangular shape (i.e. one having sharp vertices) but also shapes that are triangular in large part but not necessarily compliant with a perfect triangle having perfectly sharp vertices (corners). For example, in the embodiment shown in FIG. 5, the triangular profile is characterized by rounded corners at every vertex. However, in other embodiments, only one (or two) of the three vertices are rounded and each of the remaining one (or two) vertices is configured as a sharp corner that is defined in part by an acute angle. In yet other embodiments, all three vertices can be sharp corners.

The VCSEL 30 constitutes an individual component that can be incorporated into various types of devices either as an individual VCSEL or as one of a set of VCSELs. It should be understood that the set of VCSELs can be incorporated into the various types of devices using any of the array configurations disclosed herein. One or more of the various devices into which the VCSEL 30 is incorporated can include additional elements, such as for example, a driver chip, an optical detector (PIN diode, for example), a passive component (resistor, inductor etc.), and a power supply chip. A device incorporating one or more of the VCSEL 30 and the additional elements can be suitably packaged, such as for example, in a surface mount technology (SMT) hybrid package, or in an extended wafer-level package (eWLP).

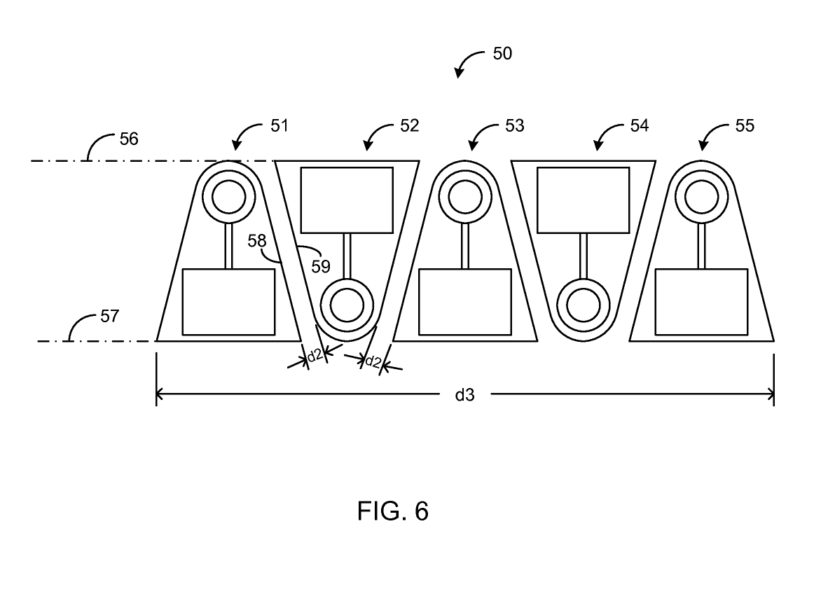

FIG. 6 shows a first example embodiment of a VCSEL array 50 in accordance with the disclosure. The VCSEL array 50 includes a number of VCSELs that are example variants of the VCSEL 30 shown in FIGS. 3-5. Each of these example variants has one rounded corner in a first vertex (the apex) of the triangular cross-sectional profile and sharp angular corners at the other two vertices. For convenience of description, the bottom edge of the triangular cross-sectional profile (interconnecting the two sharp angular corners) is referred to herein as a base portion, and each of the other two edges is referred to simply as a side.

The VCSEL array 50 is configured such that each VCSEL is positioned in an inverted position with respect to a neighboring VCSEL. Consequently, the base portion of any particular VCSEL lies alongside an apex portion of a neighboring VCSEL. Or, in other words, the base portions of any two adjacent VCSELs are located along different horizontal axes. For example, the base portion of the VCSEL 51 is aligned with a horizontal axis 57 and the base portion of the neighboring VCSEL 52 is aligned with a horizontal axis 56 that is offset with respect to the horizontal axis 57.

Furthermore, a side 58 of the VCSEL 51 is positioned parallel to a neighboring side 59 of the neighboring VCSEL 52. More particularly, the VCSEL 51 and the VCSEL 52 are arranged such that the side 58 extends along and matches the entire length of the neighboring side 59 because in this first example embodiment, the opposing extremities (base portion and apex) of the VCSEL 51 and the VCSEL 52 are aligned with each other along horizontal axes 56 and 57 respectively.

However, in a second example embodiment, VCSEL array 50 can be configured such that each VCSEL is not only positioned in an inverted position with respect to a neighboring VCSEL, but is also vertically offset with respect to the neighboring VCSEL. Thus, in this second example embodiment, the base portion of the VCSEL 51 is aligned with the horizontal axis 57 and the apex portion of the VCSEL 52 is aligned with a different horizontal axis (not shown) that is offset with respect to the horizontal axis 57. Correspondingly, the apex portion of the VCSEL 51 is aligned with the horizontal axis 56 and the base portion of the VCSEL 52 is aligned with a different horizontal axis (not shown) that is offset with respect to the horizontal axis 56. Furthermore, as a result of the vertical offset between adjacent VCSELs and unlike the first example embodiment described above, only a portion of the side 58 of the VCSEL 51 is positioned parallel to a corresponding neighboring portion of the side 59 of the VCSEL 52.

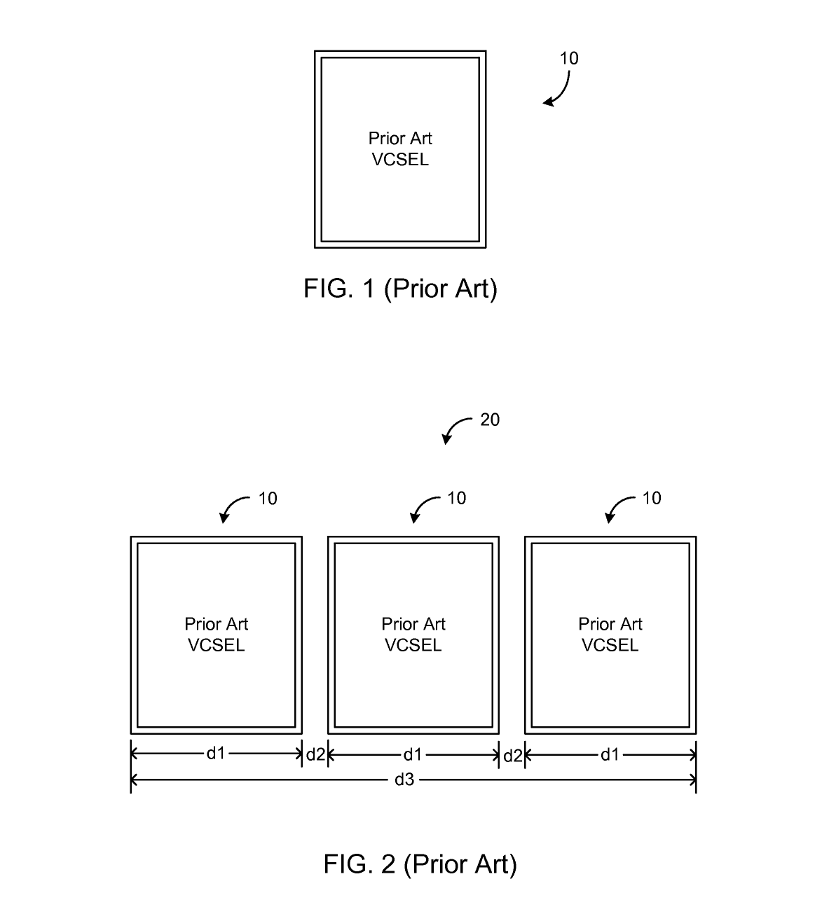

Attention is now drawn to the overall width “d3” and the inter-device spacing “d2” of the VCSEL array 50, which for purposes of comparison are identical to the overall width “d3” and the inter-device spacing “d2” of the traditional VCSEL array 20 shown in FIG. 2. Irrespective of the VCSEL array 50 being arranged in either the first or the second example embodiments described above, a comparison of the VCSEL array 50 with the traditional VCSEL array 20 shows that the arrangement of the VCSEL array 50 allows for a larger number of VCSELs to be accommodated in the same overall width “d3” without having to reduce the inter-device spacing “d2.”

Consequently, in comparison with the VCSEL array 20, the VCSEL array 50 allows for a larger batch of VCSELs to be fabricated from a single wafer during manufacture, and a larger number of VCSELs can be mounted on a substrate (such as a printed circuit board, for example) during assembly.

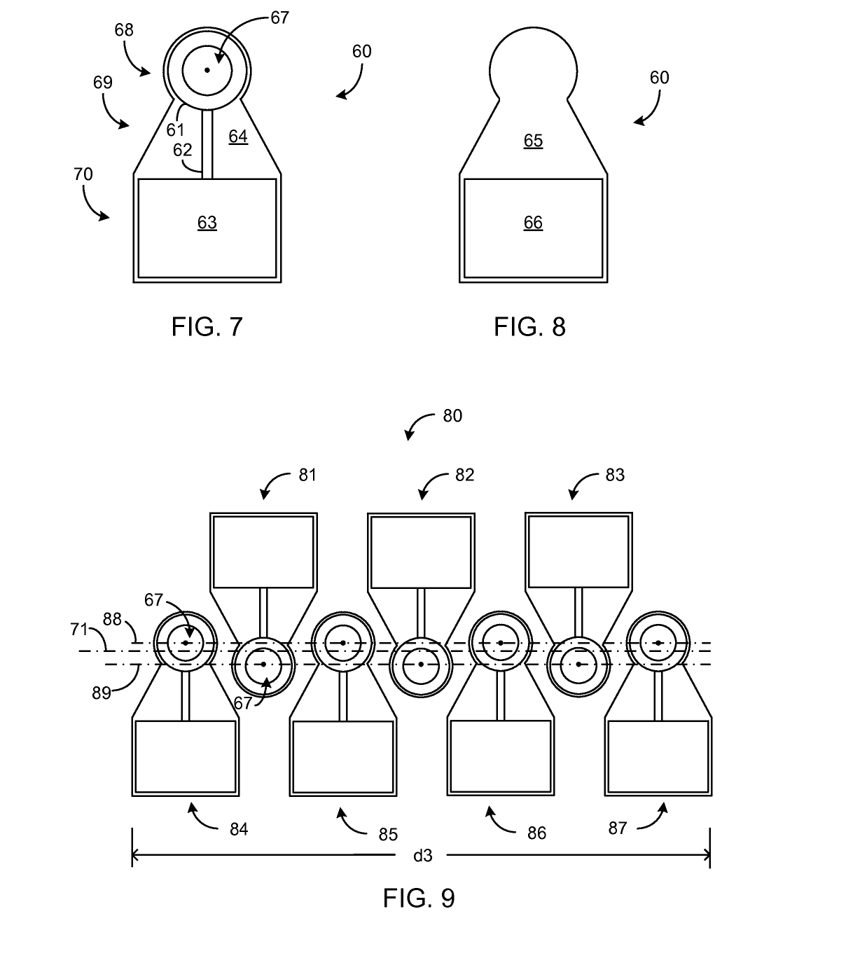

FIG. 7 shows a top view of a second example embodiment of a VCSEL 60 in accordance with the disclosure. The top view indicates a top surface 64 on which is located a first metal contact 63, an annular ring 61, and a metallic strip 62. The metallic strip 62 interconnects the first metal contact 63 and the annular ring 61. The annular ring 61 encircles an optical window 67 that is made of a transparent material that permits light to exit the VCSEL 60 out through the optical window 67. In some implementations, optical window 67 is made of a translucent material (semi-transparent material) that selectively allows light of a certain wavelength to exit the VCSEL 60 out through the optical window 67. A center of the optical window 67 is shown in FIG. 7 in the form of a dot.

FIG. 8 shows a bottom view of the VCSEL 60 shown in FIG. 7. The bottom view indicates a bottom surface 65 on which is located a second metal contact 66. Upon application of a suitable electrical voltage between the first metal contact 63 and the second metal contact 66, a laser beam (not shown) is emitted out of the optical window 67 perpendicular to the top surface 64 of the VCSEL 60.

It can be understood from FIGS. 7 and 8 that at every point of the body of the VCSEL 60 extending from the top surface 64 to the bottom surface 65, the VCSEL 60 has a cross-sectional profile that is a composite formed by combining several different shapes. In this example embodiment, the composite cross-sectional profile can be defined as a combination of a circular portion 68, a tapered neck portion 69, and a four-sided portion 70. With reference to the top surface 64, the circular portion 68 is configured to surround the annular portion 61 of the VCSEL 60. The tapered neck portion 69 extends from the circular portion 68 to the four-sided portion 70 and encompasses either the entire length or a portion of the length of the metallic strip 62. The four-sided portion 70 can have either a square shape or a rectangular shape, with one of the four sides of the rectangle (or square) merged into the tapered neck portion 69. The four-sided portion 70 generally encompasses the first metal contact 63. The bottom surface 65 has a similar composite cross-sectional profile as the top surface 64 and the four-sided portion 70 of the bottom surface 65 generally encompasses the second metal contact 66.

It should be understood that in other embodiments, the composite cross-sectional profile can be formed from various shapes other than a circular shape, a tapered shape, and a four-sided shape. For example, the circular portion 68 can have a semi-circular or oval shape, and the tapered neck portion 69 can have a rectangular shape instead. A perspective view of this second example embodiment (VCSEL 60) is not shown but can be understood in view of the perspective view of the first example embodiment (VCSEL 30) shown in FIG. 5.

FIG. 9 shows a second example embodiment of a VCSEL array 80 in accordance with the disclosure. The VCSEL array 80 includes a number of VCSELs that can be similar to the VCSEL 60 shown in FIGS. 7 and 8. The VCSEL array 80 is configured such that each VCSEL is positioned in an inverted position with respect to a neighboring VCSEL. Furthermore, in this configuration, a center of the optical window 67 of each of any two neighboring VCSELs is aligned to a different horizontal axis. For example, the center of the optical window 67 of the VCSEL 84 is aligned with a first horizontal axis 88 and the center of the optical window 67 of the VCSEL 81 is aligned with a second horizontal axis 89 that is offset with respect to the first horizontal axis 88. The offset between the first horizontal axis 88 and the second horizontal axis 89 is such that a non-central portion of each optical window 67 of adjacent VCSELs (such as for example, the VCSEL 84 and the VCSEL 81) coincides with a third horizontal axis 71.

Additionally, the circular portion 68 of the VCSEL 81 is positioned in between the tapered neck portion 69 of the VCSEL 84 and the tapered neck portion 69 of the VCSEL 85. This configuration takes advantage of the area available between the VCSEL 84 and the VCSEL 85 that are neighboring VCSELs straddling the inverted VCSEL 81. The area is formed as a result of the tapering shape of the tapered neck portions 69 of each of the VCSEL 84 and the VCSEL 85. It should be understood that a similar area can be obtained when the neck portion 69 of each of the VCSEL 84 and the VCSEL 85 has various other shapes, such as for example, an elongated rectangular shape.

In an alternative embodiment (not shown) the VCSEL array 80 is similarly configured, with each VCSEL positioned in an inverted position with respect to an adjacent VCSEL, and with a center of each optical window 67 of any two adjacent VCSELs located along different horizontal axes. Thus, the center of the optical window 67 of the VCSEL 84 is aligned with a first horizontal axis 88 and the center of the optical window 67 of the VCSEL 81 is aligned with a second horizontal axis 89 that is offset with respect to the first horizontal axis 88. However, unlike the second example embodiment described above, the offset between the first horizontal axis 88 and the second horizontal axis 89 is selected such that the third horizontal axis 71 does not intersect any of the optical windows of any of the VCSELs. In other words, a first row of VCSELs (such as the VCSEL 81, the VCSEL 82, and the VCSEL 83) is offset with respect to a second row of VCSELs (such as the VCSEL 84, the VCSEL 85, the VCSEL 86, and the VCSEL 87) to an extent that there is no portion of the optical windows of the first row of VCSELs is aligned along a common axis with any portion of the optical windows of the second row of VCSELs.

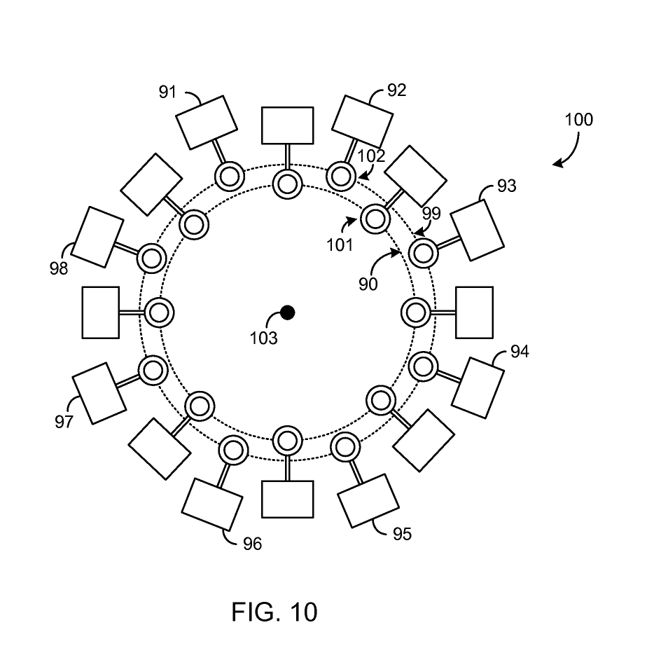

FIG. 10 shows a third example embodiment of a VCSEL array 100 in accordance with the disclosure. The VCSEL array 100 includes a number of VCSELs, each of which can be similar to the VCSEL 30 (shown in FIGS. 3-5), the VCSEL 60 (shown in FIGS. 7-8), or even a prior art VCSEL 10 (shown in FIG. 1). The VCSELS are configured as two sets of VCSELs with the optical window of each VCSEL in the two sets of VCSELs radially oriented towards a center 103 of a circle.

Specifically, each optical window of a first set of VCSELs (VCSELs 92-98) is placed at a first radial distance from a center 103 of a circle, and each optical window of the remaining VCSELs (which constitute the second set of VCSELs) is placed at a second radial distance from the center 103 of the circle. The metal contacts of each of the first and the second set of VCSELs are located farther away from the center 103 of the circle than the corresponding optical windows. At least a portion of the emitting surface of each of the first set of VCSELs is located at the second radial distance. As described above with respect to VCSEL 30 (shown in FIGS. 3-5) and the VCSEL 60 (shown in FIGS. 7-8), the emitting surface of each VCSEL includes an optical window, a metal contact, and a metallic strip (interconnect). In the example embodiment, shown in FIG. 10, the portion of the emitting surface (of each of the first set of VCSELs) that is located at the second radial distance corresponds to the metallic strip. In other embodiments, the portion of the emitting surface located at the second radial distance can include the metal contact or other areas of the emitting surface.

The first radial distance from the center 103 is indicated by the circular dashed line 99 and the second radial distance from the center 103 is indicated by the circular dashed line 90. It should be understood that in other embodiments, more than two sets of VCSELs can be arranged at various radial distances from the center 103 of the circle. The circular configuration of a VCSEL array 100 provides certain packaging advantages that will become evident in view of additional description provided below using other figures.

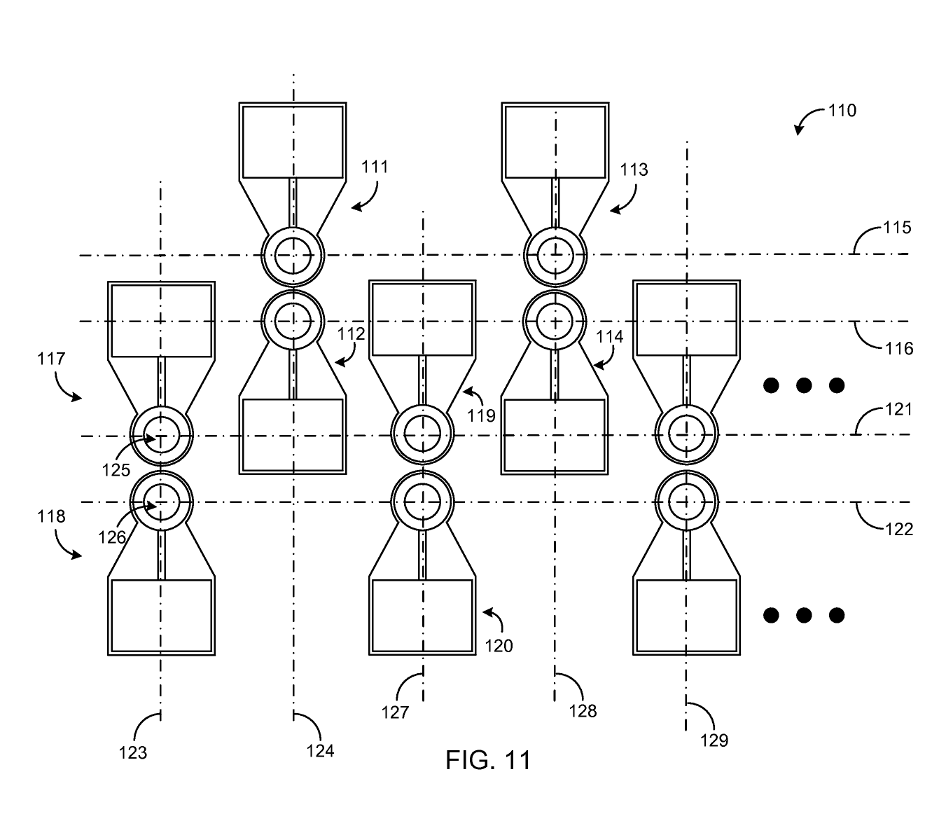

FIG. 11 shows a fourth example embodiment of a VCSEL array 110 in accordance with the disclosure. The VCSEL array 110 includes a number of VCSELs each of which can be similar to the VCSEL 60 shown in FIGS. 7 and 8. In this example embodiment, the VCSEL array 110 is configured using multiple pairs of VCSELs. Each pair of VCSELs is arranged in a head-to-head configuration with the optical window of a first VCSEL located next to and in vertical alignment with the optical window of a second VCSEL. Thus, for example, VCSEL 117 and VCSEL 118 constitute a pair of VCSELs with the optical window 125 of the VCSEL 117 located next to and in vertical alignment with the optical window 126 of the VCSEL 118. The vertical alignment is indicated by the vertical axis 123 that extends along the optical window, the tapered neck portion, and the metal contact of each of the VCSEL 117 and the VCSEL 118.

Additionally, each pair of VCSELs is offset in a vertical direction with respect to a neighboring pair of VCSELs. For example, the pair of VCSELs 117-118 is located at a lower height than the neighboring pair of VCSELs 111-112. However, each alternate pair of VCSELs of the VCSEL array 110 is located at the same height. For example, the pair of VCSELs 111-112 is located higher than the neighboring pair of VCSELs 119-120 and at the same height as the alternate pair of VCSELs 113-114.

The arrangement of the VCSELs of the VCSEL array 110 can also be described on the basis of a row and column matrix format using axes such as the horizontal axes 115, 116, 121, and 122 and the vertical axes 123, 124, 127, 128, and 129. For example, the pair of VCSELs 111 and 112 can be described on the basis of the optical window of the VCSEL 111 being located at an intersection of the horizontal axis 115 with the vertical axis 124 and the optical window of the VCSEL 111 being located at an intersection of the horizontal axis 115 with the vertical axis 124.

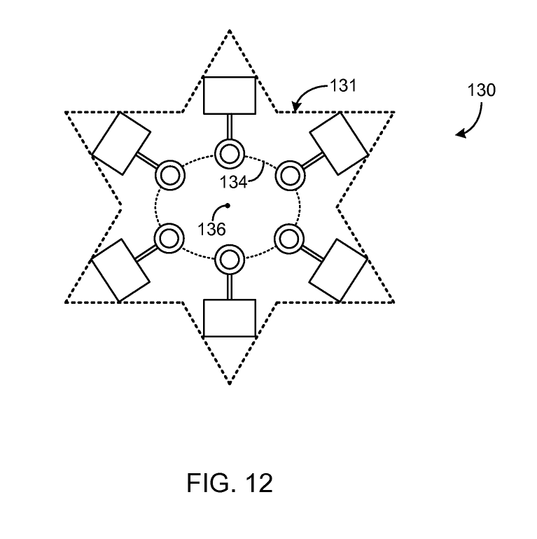

FIG. 12 shows a fifth example embodiment of a VCSEL array 130 in accordance with the disclosure. The VCSEL array 130 includes a number of VCSELs arranged in a star layout. In various implementations, each of the VCSELs can be similar to the VCSEL 30 (shown in FIGS. 3-5), the VCSEL 60 (shown in FIGS. 7-8), or even a prior art VCSEL 10 (shown in FIG. 1). In this example embodiment, each of six VCSELs is arranged at a vertex of a six-pointed star layout 131, with each VCSEL radially oriented towards a center of the six-pointed star layout 131. More particularly, the optical window of each of the six VCSELs is located closer to the center 136 of the six-pointed star layout 131 in comparison to the other parts of each of the six VCSELs.

Based on the size and orientation of the star layout (such as the star layout 131) the optical windows of a group of VCSELs can form either an oval configuration or a circular configuration. In the example embodiment, shown in FIG. 12, the six VCSELs of the group of six VCSELs form an oval configuration that is indicated by the dashed line 134. In another embodiment, the six-pointed star layout 131 can be sized and oriented such that the optical windows of the six VCSELs form a circular configuration instead of an oval configuration.

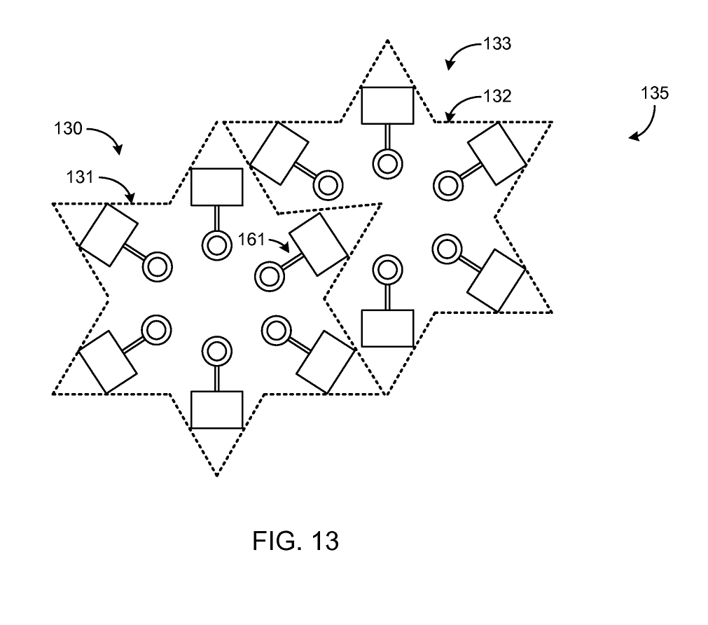

FIG. 13 shows a sixth example embodiment of a VCSEL array 135 in accordance with the disclosure. The VCSEL array 135 includes a number of VCSELs arranged in a partially overlapping star layout. In this example embodiment, a portion of the VCSEL array 130 (shown in FIG. 12) overlaps another similar VCSEL array 133. Specifically, one of the VCSELs of the VCSEL array 130 overlaps the six-pointed star layout 132 of the VCSEL array 133 and replaces one of the corresponding VCSELs of the VCSEL array 133 that could have been located in the overlap area if the VCSEL array 133 were to be an independent VCSEL array.

It should be understood that each of the other five VCSELs of the VCSEL array 130 can further overlap other neighboring VCSEL arrays (not shown), which in turn can overlap yet other VCSELS of yet other VCSEL arrays, thereby generating a mosaic of VCSEL arrays. Such an overlapping arrangement provides for a high density large scale integration of VCSELs over a given area of a substrate or other mounting surface.

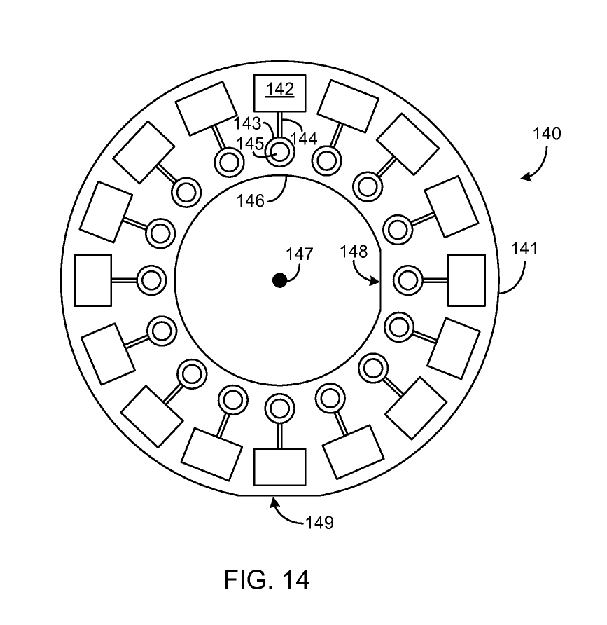

FIG. 14 shows a first example embodiment of a VCSEL array assembly 140 that incorporates an example VCSEL array in accordance with the disclosure. The VCSEL array assembly 140 includes a set of VCSELs that are mounted on a torus shaped semiconductor substrate 141. In various implementations, each of the set of VCSELs can be similar to the VCSEL 30 (shown in FIGS. 3-5), the VCSEL 60 (shown in FIGS. 7-8), or even a prior art VCSEL 10 (shown in FIG. 1). In this particular example, each of the VCSELs has a composite cross-sectional profile that can be defined in part by a circular portion 143, a rectangular neck section 144, and a four-sided portion 142. The location of each of the VCSELs can be defined and implemented in several different ways. For example, in one example implementation, each of the VCSELs is placed at an identical radial distance from a central axis 147 of the torus shaped semiconductor substrate 141. This can be carried out by placing the optical window 145 of each VCSEL at the same radial distance from the central axis 147.

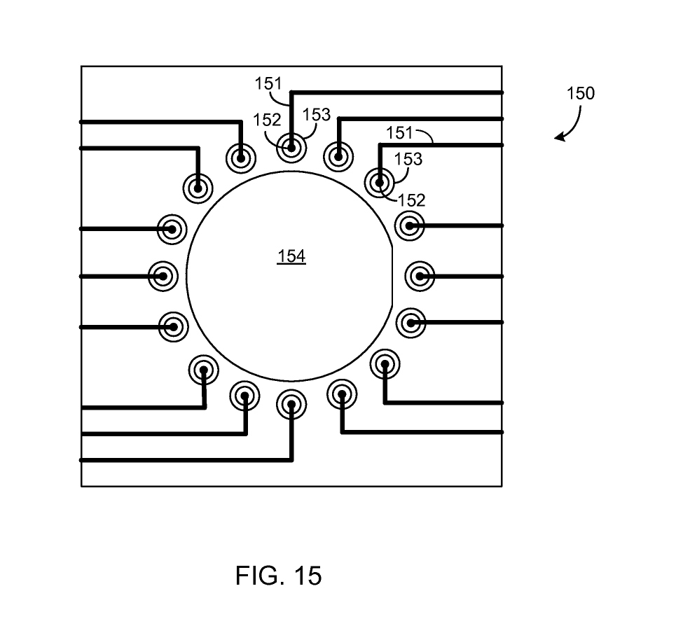

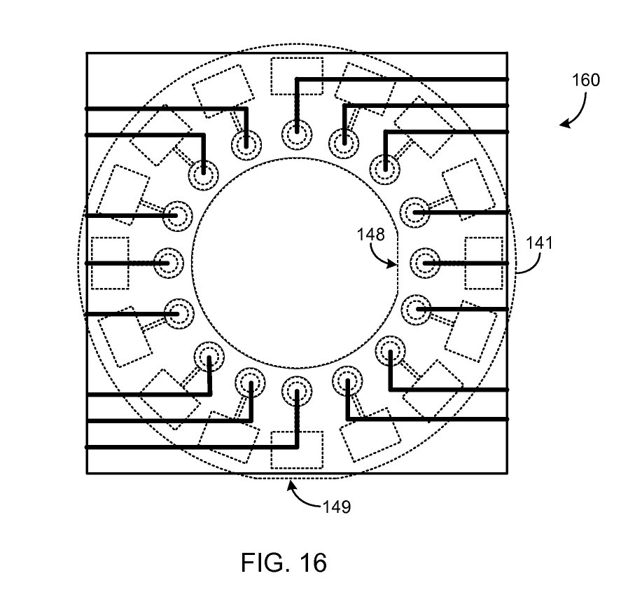

Additionally, in this example implementation, a first alignment element 148 is provided in the form of a first straight edge along the internal circular periphery of the torus shaped semiconductor substrate 141. A second alignment element 149 is also provided in the form of a second straight edge along the external circular periphery of the torus shaped semiconductor substrate 141. Each of the first alignment element 148 and the second alignment element 149 can be used for suitably orienting the torus shaped semiconductor substrate 141 during mounting of the VCSEL array assembly 140 on other objects, such as described below using FIGS. 15 and 16.

FIG. 15 shows a planar light circuit (PLC) 150 that can be coupled to the VCSEL array assembly 140 (shown in FIG. 14) in accordance with the disclosure. In this example embodiment, the PLC 150 includes a central opening 154 having a profile that matches the internal circular periphery of the torus shaped semiconductor substrate 141. The central opening 154 of the PLC 150 includes a straight edge portion that is identical to the first alignment element 148 of the torus shaped semiconductor substrate 141. Arranged around the periphery of the central opening 154 of the PLC 150 is a set of optical windows 153. Each optical window 153 includes an angled mirror 152 that receives light propagated through the optical window 153 (from below) by a VCSEL (not shown) and redirects the received light into an optical waveguide 151. The optical waveguide 151 propagates the light from the optical mirror 153 and out of an outside edge of the PLC 150. Suitable optical connectors (not shown) can be provided at the end of each optical waveguide 151 on the outside edges of the PLC 150. Alternatively, optical detectors (not shown) can be provided at the end of each optical waveguide 151 on the outside edges of the PLC 150, or at any other terminating point for each optical waveguide 151 inside the PLC 150.

FIG. 16 shows an optical assembly 160 wherein the PLC 150 (shown in FIG. 15) is coupled with the VCSEL array assembly 140 (shown in FIG. 14). The torus shaped semiconductor substrate 141 of the VCSEL array assembly 140 is shown in dashed line format to indicate that the VCSEL array assembly 140 is located underneath the PLC 150. VCSEL array assembly 140 is coupled with the PLC 150 such that the straight edge portion in the central opening 154 of the PLC 150 is aligned with the first alignment element 148 of the torus shaped semiconductor substrate 141. As a result of the alignment, each of the set of VCSELs located on the torus shaped semiconductor substrate 141 of the VCSEL array assembly 140 is automatically aligned with a corresponding optical window 153 of the PLC 150. Light emitted from each of the set of VCSELs located on the torus shaped semiconductor substrate 141 of the VCSEL array assembly 140 is propagated perpendicularly through a respective optical window 153 of the PLC 150 and routed by the optical mirror 152 and the optical waveguide 151 to the outside edge of the PLC 150 that is a part of the optical assembly 160. The second alignment element 149 of the torus shaped semiconductor substrate 141 can be used to align the optical assembly 160 with some other object (not shown).

It should be noted that the invention has been described with reference to a few illustrative embodiments for the purpose of demonstrating the principles and concepts of the invention. It will be understood by persons of skill in the art, in view of the description provided herein, that the invention is not limited to these illustrative embodiments. Persons of skill in the art will understand that many variations can be made to the illustrative embodiments without deviating from the scope of the invention.

What is claimed is:

1. A device comprising:
a first light emitting element having a substantially triangular body, the first light emitting element comprising:
a first metal contact located on a top surface; and
a metallic annular ring located on the top surface, the metallic annular ring encircling an optical window comprising at least one of a transparent material or a translucent material through which light is emitted out of the first light emitting element.

2. The device of claim 1, wherein the substantially triangular body comprises rounded corners, and wherein the first light emitting element further comprises:
a metallic strip interconnecting the first metal contact and the metallic annular ring.

3. The device of claim 1, wherein the first light emitting element is a first vertical cavity surface emitting laser (VCSEL) operable to transmit light into an optical fiber when the optical fiber is coupled to the optical window of the first VCSEL.

4. The device of claim 3, further comprising:
a second metal contact located on the bottom surface of the first VCSEL, wherein the first metal contact is operative as one of an anode or cathode terminal of the VCSEL and the second metal contact is operative as one of a corresponding cathode terminal or anode terminal respectively of the VCSEL.

5. The device of claim 1, wherein the top surface is a substantially triangular top surface, the metallic annular ring is located near a vertex of the substantially triangular top surface, and the first metal contact is located adjacent to a base portion of the substantially triangular top surface.

6. The device of claim 5, wherein the first metal contact has at least one of a square outline, a rectangular outline, a circular outline, an oval shaped outline, or a customized shape.

7. The device of claim 1, further comprising:
a second light emitting element having a substantially triangular body, the second light emitting element comprising:
a first metal contact located on a top surface; and
a metallic annular ring located on the top surface, the metallic annular ring encircling an optical window comprising at least one of a transparent material or a translucent material through which light is propagated out of the second light emitting element, and
wherein at least a portion of one side of the second light emitting element is positioned parallel to a neighboring side of the first light emitting element.

8. The device of claim 7, wherein the first light emitting element is a first vertical cavity surface emitting laser (VCSEL), the second light emitting element is a second VCSEL, and the first VCSEL is located adjacent to the second VCSEL with the second VCSEL oriented in an inverted position with respect to the first VCSEL.

9. A device comprising:
a first set of vertical cavity surface emitting lasers (VCSELs), each VCSEL having an emitting surface comprising an optical window and a metal contact; and
a substrate on which the first set of VCSELs is arranged in one of an oval configuration or a first circular configuration, the one of the oval configuration or the first circular configuration defined at least in part by the optical window of each VCSEL of the first set of VCSELs being located closer to a center of the one of an oval configuration or the circular configuration than the metal contact on each VCSEL of the first set of VCSELs.

10. The device of claim 9, wherein the first circular configuration is further defined by the optical window of each of the first set of VCSELs being located at a first radial distance from the center of the first circular configuration.

11. The device of claim 10, wherein the substrate is a torus shaped semiconductor substrate with a central axis of the torus shaped semiconductor substrate corresponding to the center of the first circular configuration, and wherein the first radial distance places the optical window of each VCSEL in the first set of VCSELs along an inner periphery of the torus shaped semiconductor substrate.

12. The device of claim 11, wherein the torus shaped semiconductor substrate further comprises a second set of VCSELs arranged in a second circular configuration defined at least in part by an optical window of each of the second set of VCSELs being located at a second radial distance from the central axis of the torus shaped semiconductor substrate.

13. The device of claim 12, wherein a portion of the emitting surface of each VCSEL in the first set of VCSELs is located at the second radial distance from the central axis of the torus shaped semiconductor substrate.

14. The device of claim 12, further comprising:
a planar light circuit (PLC) comprising a plurality of optical waveguides, the torus shaped semiconductor substrate attached to the PLC in a flip chip arrangement whereby light emitted by each of the first set of VCSELs is transmitted into a respective one of a first set of optical waveguides amongst the plurality of optical waveguides, and light emitted by each of the second set of VCSELs is transmitted into a respective one of a second set of optical waveguides amongst the plurality of optical waveguides.

15. A device comprising:
a first vertical cavity surface emitting laser (VCSEL) having a top surface on which is located a first metal contact and a first optical window, the first optical window configured for propagating light out of the first VCSEL;
a second VCSEL having a top surface on which is located a second metal contact and a second optical window, the second optical window configured for propagating light out of the second VCSEL; and
a third VCSEL having a top surface on which is located a third metal contact and a third optical window, the third optical window configured for propagating light out of the third VCSEL,
wherein the first optical window and the third optical window are aligned along a first horizontal axis and the second optical window is aligned along a second horizontal axis that is offset with respect to the first horizontal axis.

16. The device of claim 15, wherein the offset selected such that at least a portion of each of the first, second, and third optical windows is aligned along a third horizontal axis located between the first horizontal axis and the second horizontal axis.

17. The device of claim 16, wherein each of the first, second, and third VCSELs has a substantially triangular body.

18. The device of claim 17, wherein each of the first, second, and third optical window is respectively located near a vertex of a substantially triangular top surface of each of the first, second, and third VCSELs, and each of the first, second, and third metal contacts is respectively located adjacent to a base portion of the substantially triangular top surface of each of the first, second, and third VCSELs.

19. The device of claim 16, wherein each of a top surface and a bottom surface of each the first, second, and third VCSELs has a composite cross-sectional profile comprising a tapered neck portion.

20. The device of claim 19, wherein each of the first, second, and third optical windows is respectively located on one side of the tapered neck portion and each of the first, second, and third metal contacts is respectively located on an opposing side of the tapered neck portion.
